(19) United States
(12) Patent Application Publication
(10) Pub. No.: US 2009/0149008 A1
(43) Pub. Date: Jun. 11, 2009

(54) METHOD FOR DEPOSITING GROUP III/V COMPOUNDS

(75) Inventors: Olga Kryliouk, Santa Clara, CA (US); Sandeep Nijhawan, Los Altos, CA (US); Yuriy Melnik, Santa Clara, CA (US); Lori D. Washington, Union City, CA (US); Jacob W. Grayson, Santa Clara, CA (US); Sung W. Jun, Sunnyvale, CA (US); Jie Su, Santa Clara, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: Applied Materials, Inc.

(21) Appl. No.: 12/244,440

(22) Filed: Oct. 2, 2008

Related U.S. Application Data
(60) Provisional application No. 60/978,040, filed on Oct. 5, 2007.

(51) Int. Cl. H01L 21/20

(52) U.S. Cl. 438/503; 257/E21.09

(57) ABSTRACT

Embodiments of the invention generally relate to methods for forming Group III-V materials by a hydride vapor phase epitaxy (HVPE) process. In one embodiment, a method for forming a gallium nitride material on a substrate within a processing chamber is provided which includes heating a metallic source to form a heated metallic source, wherein the heated metallic source contains gallium, aluminum, indium, alloys thereof, or combinations thereof, exposing the heated metallic source to chlorine gas while forming a metallic chloride gas, exposing the substrate to the metallic chloride gas and a nitrogen precursor gas while forming a metal nitride layer on the substrate during the HVPE process. The method further provides exposing the substrate to chlorine gas during a pretreatment process prior to forming the metal nitride layer. In one example, the exhaust conduit of the processing chamber is heated to about 200° C. or less during the pretreatment process.

### CROSS-REFERENCE TO RELATED APPLICATION

This application claims benefit of U.S. Ser. No. 60/978,040 (APPM/011926L), filed Oct. 5, 2007, which is herein incorporated by reference in its entirety.

### BACKGROUND OF THE INVENTION

1. Field of the Invention

Embodiments of the invention generally relate to the manufacturing of devices, such as light emitting diodes (LEDs), and, more particularly, to processes for forming Group III-V materials by metal-organic chemical vapor deposition (MOCVD) processes and hydride vapor phase epitaxy (HVPE) deposition processes.

2. Description of the Related Art

Group III nitride semiconductors are finding greater importance in the development and fabrication of a variety of semiconductor devices, such as short wavelength light emitting diodes (LEDs), laser diodes (LDs), and electronic devices including high power, high frequency, high temperature transistors and integrated circuits. One method that has been used to deposit Group III nitrides is hydride vapor phase epitaxy (HVPE) deposition. In HVPE, a halogen compound reacts with the Group III metal or element to form the respective metal/element halide precursor (e.g., metal chloride). The halide precursor then reacts with a nitrogen precursor gas to form the Group III nitride.

As the demand for LEDs, LDs, transistors, and integrated circuits increases, the efficiency of depositing Group III nitrides and other Group III-V materials takes on greater importance. There is a general need for a deposition apparatus and process with a high deposition rate that can deposit films uniformly over a large substrate or multiple substrates. Additionally, uniform precursor mixing is desirable for consistent film quality over the substrate. Therefore, there is a need in the art for an improved HVPE deposition method.

### SUMMARY OF THE INVENTION

Embodiments of the invention generally relate to methods for forming Group III-V materials by metal-organic chemical vapor deposition (MOCVD) and hydride vapor phase epitaxy (HVPE) processes. In one embodiment, a method for forming a gallium nitride material on a substrate is provided which includes heating a solid metallic gallium source to form a liquid metallic gallium source, exposing the liquid metallic gallium source to chlorine gas (Cl₂) to form a gallium chloride gas, and exposing the substrate within a processing chamber to the gallium chloride gas and a nitrogen precursor gas while forming a gallium nitride layer on the substrate during a HVPE process.

In some embodiments, the substrate may be exposed to a pretreatment gas containing chlorine gas during a pretreatment process prior to forming the gallium nitride layer. Some examples provide that the pretreatment gas further contains ammonia, gallium chloride, argon, nitrogen, hydrogen, or combinations thereof. In some examples, the method further provides that the nitrogen precursor gas contains ammonia. The chlorine gas may have a flow rate within a range from about 50 sccm to about 4,000 sccm, such as from about 50 sccm to about 1,000 sccm during the pretreatment process. The substrate may be heated to a temperature within a range from about 500° C. to about 1,250° C., preferably, from about 800° C. to about 1,100° C. during the HVPE process or the pretreatment process.

In other examples, the processing chamber may be exposed to the chlorine gas during a chamber clean process subsequent to forming the gallium nitride layer. The processing chamber may be heated to a temperature within a range about 500° C. to about 1,250° C. during the chamber clean process. In some examples, the processing chamber may be exposed to a plasma during the chamber clean process.

In another embodiment, a method for forming an aluminum nitride material on a substrate is provided which includes heating a metallic aluminum source, exposing the heated metallic aluminum source to chlorine gas while forming an aluminum chloride gas, and exposing the substrate within the processing chamber to the aluminum chloride gas and a nitrogen precursor gas while forming an aluminum nitride layer on the substrate during a HVPE process.

In some embodiments, the substrate may be exposed to a pretreatment gas containing chlorine gas during the pretreatment process prior to forming the aluminum nitride layer. Some examples provide that the pretreatment gas further contains ammonia, aluminum chloride, argon, nitrogen, hydrogen, or combinations thereof. In some examples, the method further provides that the nitrogen precursor gas contains ammonia. The chlorine gas may have a flow rate within a range from about 50 sccm to about 4,000 sccm, such as from about 50 sccm to about 1,000 sccm during the pretreatment process. The substrate may be heated to a temperature within a range from about 500° C. to about 1,250° C., preferably, from about 800° C. to about 1,100° C. during the HVPE process or the pretreatment process.

In other examples, the processing chamber may be exposed to the chlorine gas during a chamber clean process subsequent to forming the aluminum nitride layer. The processing chamber may be heated to a temperature within a range about 500° C. to about 1,250° C. during the chamber clean process. In some examples, the processing chamber may be exposed to a plasma during the chamber clean process.

In another embodiment, a method for forming a gallium nitride material on a substrate is provided which includes exposing the substrate to chlorine gas while forming a pretreated surface during a pretreatment process, heating a metallic source to form a heated metallic source, wherein the heated metallic source contains gallium, aluminum, indium, alloys thereof, or combinations thereof, and exposing the heated metallic source to chlorine gas while forming a metallic chloride gas. The method further provides exposing the substrate to the metallic chloride gas and a nitrogen precursor gas while forming a metal nitride layer on the pretreated surface during a HVPE process.

In another embodiment, a method for forming a gallium nitride material on a substrate is provided which includes heating a metallic source to form a heated metallic source, wherein the heated metallic source contains gallium, aluminum, indium, alloys thereof, or combinations thereof, exposing the heated metallic source to chlorine gas while forming a metallic chloride gas, and exposing the substrate within the processing chamber to the metallic chloride gas and a nitrogen precursor gas while forming a metal nitride layer on the substrate during a HVPE process. The method further provides exposing the processing chamber to the chlorine gas during a chamber clean process subsequent to forming the metal nitride layer. The substrate may be removed from the processing chamber prior to the chamber clean process. The processing chamber may be heated to a temperature within a range about 500° C. to about 1,200° C. during clean process. Optionally, the processing chamber may be exposed to a plasma during the chamber clean process.

In another embodiment, a method for forming a gallium-containing material on a substrate is provided which includes heating a solid metallic gallium source to form a liquid metallic gallium source, exposing the liquid metallic gallium source to chlorine gas while forming a gallium chloride gas, and exposing the substrate to the gallium chloride gas and a Group V precursor gas while forming a gallium-containing layer on the substrate during a HVPE process.

In another embodiment, a method for forming an aluminum-containing material on a substrate is provided which includes heating a metallic aluminum source, exposing the heated metallic aluminum source to chlorine gas while forming an aluminum chloride gas, and exposing the substrate within a processing chamber to the aluminum chloride gas and a Group V precursor gas while forming an aluminum-containing layer on the substrate during a HVPE process.

The Group V precursor gas may contain an element such as nitrogen, phosphorous, arsenic, or combinations thereof. In one example, the Group V precursor gas may contain ammonia, hydrazine compounds, amine compounds, derivatives thereof, or combinations thereof. In another example, the Group V precursor gas may contain phosphine, an alkyl phosphine compound, arsine, an alkyl arsine compound, derivatives thereof, or combinations thereof.

In another embodiment, a method for forming a Group III nitride material on a substrate is provided which includes heating a trialkyl Group III compound to a predetermined temperature, exposing the trialkyl Group III compound to chlorine gas while forming a metal chloride gas, and exposing the substrate within a processing chamber to the metal chloride gas and a nitrogen precursor gas while forming a metal nitride layer on the substrate during a vapor deposition process.

In one example, the trialkyl Group III compound contains a trialkylgallium compound and the metal chloride gas contains gallium chloride. The trialkylgallium compound may contain an alkyl group such as methyl, ethyl, propyl, butyl, isomers thereof, derivatives thereof, or combinations thereof. The gallium chloride may be formed at a temperature within a range from about 300° C. to about 600° C. However, the substrate may be heated to a temperature within a range from about 800° C. to about 1,100° C. during the vapor deposition process.

In another example, the trialkyl Group III compound contains a trialkylaluminum compound and the metal chloride gas contains aluminum chloride. The trialkylaluminum compound may contain an alkyl group selected from methyl, ethyl, propyl, butyl, isomers thereof, derivatives thereof, or combinations thereof. The aluminum chloride may be formed at a temperature within a range from about 300° C. to about 400° C. However, the substrate may be heated to a temperature within a range from about 800° C. to about 1,100° C. during the vapor deposition process.

In another example, the trialkyl Group III compound contains a trialkylindium compound and the metal chloride gas contains indium chloride. The trialkylindium compound may contain an alkyl group selected from methyl, ethyl, propyl, butyl, isomers thereof, derivatives thereof, or combinations thereof. The indium chloride may be formed at a temperature within a range from about 300° C. to about 400° C. However, the substrate may be heated to a temperature within a range from about 500° C. to about 650° C. during the vapor deposition process.

In some embodiments, the substrate may be exposed to the chlorine gas during a pretreatment process prior to forming the metal nitride layer. The substrate may be heated to a temperature within a range about 500° C. to about 1,200° C. during the pretreatment process. The processing chamber may be exposed to the chlorine gas during a chamber clean process subsequent to forming the metal nitride layer. In other examples, the processing chamber may be heated to a temperature within a range about 500° C. to about 1,200° C. during the chamber clean process. The processing chamber may be exposed to a plasma during the chamber clean process.

In another embodiment, a method for forming a gallium nitride material on a substrate is provided which includes exposing a substrate within a processing chamber to chlorine gas while forming a pretreated surface during a pretreatment process, and heating a metallic source to form a heated metallic source, wherein the heated metallic source contains an element such as gallium, aluminum, indium, alloys thereof, or combinations thereof. The method further includes exposing the heated metallic source to a chlorine-containing gas while forming a metallic chloride gas, and exposing the substrate to the metallic chloride gas and a nitrogen precursor gas while forming a metal nitride layer on the pretreated surface during a HVPE process. Examples provide that the chlorine-containing gas contains chlorine gas or hydrogen chloride (HCl).

In another embodiment, a method for forming a Group III nitride material on a substrate is provided which includes heating a trialkyl Group III compound to a predetermined temperature, wherein the trialkyl Group III compound has the chemical formula of R″R′RM, where M is gallium, aluminum, or indium, and each R″, R′, and R is independently selected from methyl, ethyl, propyl, butyl, isomers thereof, derivatives thereof, or combinations thereof. The method further provides exposing chlorine gas to the trialkyl Group III compound while forming a metal chloride gas and exposing the substrate within the processing chamber to the metal chloride gas and a nitrogen precursor gas while forming a metal nitride layer on the substrate during a vapor deposition process.

In another embodiment, a method for forming a gallium nitride material on a substrate is provided which includes providing the substrate within a processing chamber coupled to an exhaust system, wherein the exhaust system has an exhaust conduit, exposing the substrate to a pretreatment gas containing chlorine gas while forming a pretreated surface during a pretreatment process, while heating the exhaust conduit to a temperature of about 200° C. or less during the pretreatment process. The method further includes heating a solid metallic gallium source to form a liquid metallic gallium source, exposing the liquid metallic gallium source to the chlorine gas while forming a gallium chloride gas, and exposing the substrate to the gallium chloride gas and a nitrogen precursor gas while forming a gallium nitride layer on the substrate during a HVPE process.

Examples provide that the exhaust conduit may be heated to a temperature of about 170° C. or less, such as about 150° C. or less, such as about 130° C. or less, such as about 100° C. or less, such as about 70° C. or less, such as about 50° C. or less, during the pretreatment process. In other examples, the exhaust conduit may be heated during the pretreatment process to a temperature within a range from about 30° C. to about 200° C., preferably, from about 30° C. to about 170° C., more preferably, from about 30° C. to about 150° C., more preferably, from about 50° C. to about 120° C., and more preferably, from about 50° C. to about 100° C. The processing chamber may have an internal pressure of about 760 Torr or less during the pretreatment process, preferably, within a range from about 100 Torr to about 760 Torr, more preferably, from about 200 Torr to about 760 Torr, and more preferably, from about 350 Torr to about 760 Torr, for example, about 450 Torr.

In another embodiment, the substrate may be exposed to a pretreatment gas containing chlorine gas and ammonia gas during the HVPE process. In some examples, the pretreatment gas contains chlorine gas at a concentration within a range from about 1 molar percent (mol %) to about 10 mol %, preferably, from about 3 mol % to about 7 mol %, and more preferably, from about 4 mol % to about 6 mol %, for example, about 5 mol %. In other example, the pretreatment gas contains ammonia gas at a concentration within a range from about 5 mol % to about 25 mol %, preferably, from about 10 mol % to about 20 mol %, and more preferably, from about 12 mol % to about 18 mol %, for example, about 15 mol %.

In another embodiment, the processing chamber contains a deposition gas containing chlorine gas and ammonia gas during the HVPE process. The deposition gas contains chlorine gas at a concentration within a range from about 0.01 mol % to about 1 mol %, preferably, from about 0.05 mol % to about 0.5 mol %, and more preferably, from about 0.07 mol % to about 0.4 mol %, for example, about 0.1 mol %. In other examples, the deposition gas contains ammonia gas at a concentration within a range from about 5 mol % to about 25 mol %, preferably, from about 10 mol % to about 20 mol %, and more preferably, from about 12 mol % to about 18 mol %, for example, about 15 mol %.

In other embodiments, the exhaust conduit may be heated to a temperature of about 200° C. or less during a HVPE process or a chamber clean process. Examples provide that the exhaust conduit may be heated to a temperature of about 170° C. or less, such as about 150° C. or less, such as about 130° C. or less, such as about 100° C. or less, such as about 70° C. or less, such as about 50° C. or less, during the HVPE process or the chamber clean process. In other examples, the exhaust conduit may be heated during the HVPE process or the chamber clean process to a temperature within a range from about 30° C. to about 200° C., preferably, from about 30° C. to about 170° C., more preferably, from about 30° C. to about 150° C., more preferably, from about 50° C. to about 120° C., and more preferably, from about 50° C. to about 100° C.

The processing chamber may have an internal pressure of about 760 Torr or less during the HVPE process or the chamber clean process, preferably, within a range from about 100 Torr to about 760 Torr, more preferably, from about 200 Torr to about 760 Torr, and more preferably, from about 350 Torr to about 760 Torr, for example, about 450 Torr. In some examples, the clean gas contains chlorine gas at a concentration within a range from about 1 mol % to about 10 mol %, preferably, from about 3 mol % to about 7 mol %, and more preferably, from about 4 mol % to about 6 mol %, for example, about 5 mol %.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings.

FIG. 1 depicts a cross-sectional view of a deposition chamber according to one embodiment of the invention;

FIG. 2 depicts a cross-sectional perspective side-view of a showerhead assembly according to one embodiment of the invention;

FIG. 3 depicts a cross-sectional top-view of a showerhead assembly according to one embodiment of the invention;

FIG. 4 depicts a cross-sectional perspective cutaway-view of a showerhead assembly according to one embodiment of the invention;

FIGS. 5A-5B depict view of the gas passage components of a showerhead assembly according to one embodiment of the invention;

FIG. 6 depicts a perspective view of the top plate component of a showerhead assembly according to one embodiment of the invention;

FIG. 7 depicts a cross-sectional perspective side-view of a showerhead assembly according to one embodiment of the invention;

FIGS. 8A-8C depict views of the boat components of a showerhead assembly according to one embodiment of the invention; and

FIGS. 9A-9B depict views of the gas passage components of a showerhead assembly according to one embodiment of the invention.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the invention generally relate to methods for forming Group III-V materials by metal-organic chemical vapor deposition (MOCVD) and hydride vapor phase epitaxy (HVPE) processes. In one embodiment, a method for forming a gallium nitride material on a substrate is provided which includes heating a solid metallic gallium source to form a liquid metallic gallium source, exposing the liquid metallic gallium source to chlorine gas (Cl₂) to form a gallium chloride gas, and exposing the substrate within a processing chamber to the gallium chloride gas and a nitrogen precursor gas while forming a gallium nitride layer on the substrate during a HVPE process.

In some embodiments, the substrate may be exposed to a pretreatment gas containing chlorine gas during a pretreatment process prior to forming the gallium nitride layer. Some examples provide that the pretreatment gas further contains ammonia, gallium chloride, argon, nitrogen, hydrogen, or combinations thereof. In some examples, the method further provides that the nitrogen precursor gas contains ammonia. The chlorine gas may have a flow rate within a range from about 50 sccm to about 4,000 sccm, such as from about 50 sccm to about 1,000 sccm during the pretreatment process. The substrate may be heated to a temperature within a range from about 500° C. to about 1,250° C., preferably, from about 800° C. to about 1,100° C. during the HVPE process or the pretreatment process.

In other examples, the processing chamber may be exposed to the chlorine gas during a chamber clean process subsequent to forming the gallium nitride layer. The processing chamber may be heated to a temperature within a range about 500° C. to about 1,250° C. during the chamber clean process. In some examples, the processing chamber may be exposed to a plasma during the chamber clean process.

In another embodiment, a method for forming an aluminum nitride material on a substrate is provided which includes heating a metallic aluminum source, exposing the heated metallic aluminum source to chlorine gas while forming an aluminum chloride gas, and exposing the substrate within the processing chamber to the aluminum chloride gas and a nitrogen precursor gas while forming an aluminum nitride layer on the substrate during a HVPE process.

In some embodiments, the substrate may be exposed to a pretreatment gas containing chlorine gas during the pretreatment process prior to forming the aluminum nitride layer. Some examples provide that the pretreatment gas further contains ammonia, aluminum chloride, argon, nitrogen, hydrogen, or combinations thereof. In some examples, the method further provides that the nitrogen precursor gas contains ammonia. The chlorine gas may have a flow rate within a range from about 50 sccm to about 4,000 sccm, such as from about 50 sccm to about 1,000 sccm during the pretreatment process. The substrate may be heated to a temperature within a range from about 500° C. to about 1,250° C., preferably, from about 800° C. to about 1,100° C. during the HVPE process or the pretreatment process.

In other examples, the processing chamber may be exposed to the chlorine gas during a chamber clean process subsequent to forming the aluminum nitride layer. The processing chamber may be heated to a temperature within a range about 500° C. to about 1,250° C. during the chamber clean process. In some examples, the processing chamber may be exposed to a plasma during the chamber clean process.

In another embodiment, a method for forming a gallium nitride material on a substrate is provided which includes exposing the substrate to chlorine gas while forming a pretreated surface during a pretreatment process, heating a metallic source to form a heated metallic source, wherein the heated metallic source contains gallium, aluminum, indium, alloys thereof, or combinations thereof, and exposing the heated metallic source to chlorine gas while forming a metallic chloride gas. The method further provides exposing the substrate to the metallic chloride gas and a nitrogen precursor gas while forming a metal nitride layer on the pretreated surface during a HVPE process.

In another embodiment, a method for forming a gallium nitride material on a substrate is provided which includes heating a metallic source to form a heated metallic source, wherein the heated metallic source contains gallium, aluminum, indium, alloys thereof, or combinations thereof, exposing the heated metallic source to chlorine gas while forming a metallic chloride gas, and exposing the substrate within the processing chamber to the metallic chloride gas and a nitrogen precursor gas while forming a metal nitride layer on the substrate during a HVPE process. The method further provides exposing the processing chamber to the chlorine gas during a chamber clean process subsequent to forming the metal nitride layer. The substrate may be removed from the processing chamber prior to the chamber clean process. The processing chamber may be heated to a temperature within a range about 500° C. to about 1,200° C. during clean process. Optionally, the processing chamber may be exposed to a plasma during the chamber clean process.

In another embodiment, a method for forming a gallium-containing material on a substrate is provided which includes heating a solid metallic gallium source to form a liquid metallic gallium source, exposing the liquid metallic gallium source to chlorine gas while forming a gallium chloride gas, and exposing the substrate to the gallium chloride gas and a Group V precursor gas while forming a gallium-containing layer on the substrate during a HVPE process.

In another embodiment, a method for forming an aluminum-containing material on a substrate is provided which includes heating a metallic aluminum source, exposing the heated metallic aluminum source to chlorine gas while forming an aluminum chloride gas, and exposing the substrate within a processing chamber to the aluminum chloride gas and a Group V precursor gas while forming an aluminum-containing layer on the substrate during a HVPE process.

The Group V precursor gas may contain an element such as nitrogen, phosphorous, arsenic, or combinations thereof. In one example, the Group V precursor gas may contain ammonia, hydrazine compounds, amine compounds, derivatives thereof, or combinations thereof. In another example, the Group V precursor gas may contain phosphine, an alkyl phosphine compound, arsine, an alkyl arsine compound, derivatives thereof, or combinations thereof.

In another embodiment, a method for forming a Group III nitride material on a substrate is provided which includes heating a trialkyl Group III compound to a predetermined temperature, exposing the trialkyl Group III compound to chlorine gas while forming a metal chloride gas, and exposing the substrate within a processing chamber to the metal chloride gas and a nitrogen precursor gas while forming a metal nitride layer on the substrate during a vapor deposition process.

In one example, the trialkyl Group III compound contains a trialkylgallium compound and the metal chloride gas contains gallium chloride. The trialkylgallium compound may contain an alkyl group such as methyl, ethyl, propyl, butyl, isomers thereof, derivatives thereof, or combinations thereof. The gallium chloride may be formed at a temperature within a range from about 300° C. to about 600° C. However, the substrate may be heated to a temperature within a range from about 800° C. to about 1,100° C. during the vapor deposition process.

In another example, the trialkyl Group III compound contains a trialkylaluminum compound and the metal chloride gas contains aluminum chloride. The trialkylaluminum compound may contain an alkyl group selected from methyl, ethyl, propyl, butyl, isomers thereof, derivatives thereof, or combinations thereof. The aluminum chloride may be formed at a temperature within a range from about 300° C. to about 400° C. However, the substrate may be heated to a temperature within a range from about 800° C. to about 1,100° C. during the vapor deposition process.

In another example, the trialkyl Group III compound contains a trialkylindium compound and the metal chloride gas contains indium chloride. The trialkylindium compound may contain an alkyl group selected from methyl, ethyl, propyl, butyl, isomers thereof, derivatives thereof, or combinations thereof. The indium chloride may be formed at a temperature within a range from about 300° C. to about 400° C. However, the substrate may be heated to a temperature within a range from about 500° C. to about 650° C. during the vapor deposition process.

In some embodiments, the substrate may be exposed to the chlorine gas during a pretreatment process prior to forming the metal nitride layer. The substrate may be heated to a temperature within a range about 500° C. to about 1,200° C. during the pretreatment process. The processing chamber may be exposed to the chlorine gas during a chamber clean process subsequent to forming the metal nitride layer. In other examples, the processing chamber may be heated to a temperature within a range about 500° C. to about 1,200° C. during the chamber clean process. The processing chamber may be exposed to a plasma during the chamber clean process.

In another embodiment, a method for forming a gallium nitride material on a substrate is provided which includes exposing a substrate within a processing chamber to chlorine gas while forming a pretreated surface during a pretreatment process, and heating a metallic source to form a heated metallic source, wherein the heated metallic source contains an element such as gallium, aluminum, indium, alloys thereof, or combinations thereof. The method further includes exposing the heated metallic source to a chlorine-containing gas while forming a metallic chloride gas, and exposing the substrate to the metallic chloride gas and a nitrogen precursor gas while forming a metal nitride layer on the pretreated surface during a HVPE process. Examples provide that the chlorine-containing gas contains chlorine gas or hydrogen chloride (HCl).

In another embodiment, a method for forming a Group III nitride material on a substrate is provided which includes heating a trialkyl Group III compound to a predetermined temperature, wherein the trialkyl Group III compound has the chemical formula of R″R′RM, where M is gallium, aluminum, or indium, and each R″, R′, and R is independently selected from methyl, ethyl, propyl, butyl, isomers thereof, derivatives thereof, or combinations thereof. The method further provides exposing chlorine gas to the trialkyl Group III compound while forming a metal chloride gas and exposing the substrate within the processing chamber to the metal chloride gas and a nitrogen precursor gas while forming a metal nitride layer on the substrate during a vapor deposition process.

In another embodiment, a method for forming a gallium nitride material on a substrate is provided which includes providing the substrate within a processing chamber coupled to an exhaust system, wherein the exhaust system has an exhaust conduit, exposing the substrate to a pretreatment gas containing chlorine gas while forming a pretreated surface during a pretreatment process, while heating the exhaust conduit to a temperature of about 200° C. or less during the pretreatment process. The method further includes heating a solid metallic gallium source to form a liquid metallic gallium source, exposing the liquid metallic gallium source to the chlorine gas while forming a gallium chloride gas, and exposing the substrate to the gallium chloride gas and a nitrogen precursor gas while forming a gallium nitride layer on the substrate during a HVPE process.

Examples provide that the exhaust conduit may be heated to a temperature of about 170° C. or less, such as about 150° C. or less, such as about 130° C. or less, such as about 100° C. or less, such as about 70° C. or less, such as about 50° C. or less, during the pretreatment process. In other examples, the exhaust conduit may be heated during the pretreatment process to a temperature within a range from about 30° C. to about 200° C., preferably, from about 30° C. to about 170° C., more preferably, from about 30° C. to about 150° C., more preferably, from about 50° C. to about 120° C., and more preferably, from about 50° C. to about 100° C. The processing chamber may have an internal pressure of about 760 Torr or less during the pretreatment process, preferably, within a range from about 100 Torr to about 760 Torr, more preferably, from about 200 Torr to about 760 Torr, and more preferably, from about 350 Torr to about 760 Torr, for example, about 450 Torr.

In another embodiment, the substrate may be exposed to a pretreatment gas containing chlorine gas and ammonia gas during the HVPE process. In some examples, the pretreatment gas contains chlorine gas at a concentration within a range from about 1 molar percent (mol %) to about 10 mol %, preferably, from about 3 mol % to about 7 mol %, and more preferably, from about 4 mol % to about 6 mol %, for example, about 5 mol %. In other example, the pretreatment gas contains ammonia gas at a concentration within a range from about 5 mol % to about 25 mol %, preferably, from about 10 mol % to about 20 mol %, and more preferably, from about 12 mol % to about 18 mol %, for example, about 15 mol %.

In another embodiment, the processing chamber contains a deposition gas containing chlorine gas and ammonia gas during the HVPE process. The deposition gas contains chlorine gas at a concentration within a range from about 0.01 mol % to about 1 mol %, preferably, from about 0.05 mol % to about 0.5 mol %, and more preferably, from about 0.07 mol % to about 0.4 mol %, for example, about 0.1 mol %. In other examples, the deposition gas contains ammonia gas at a concentration within a range from about 5 mol % to about 25 mol %, preferably, from about 10 mol % to about 20 mol %, and more preferably, from about 12 mol % to about 18 mol %, for example, about 15 mol %.

In other embodiments, the exhaust conduit may be heated to a temperature of about 200° C. or less during a HVPE process or a chamber clean process. Examples provide that the exhaust conduit may be heated to a temperature of about 170° C. or less, such as about 150° C. or less, such as about 130° C. or less, such as about 100° C. or less, such as about 70° C. or less, such as about 50° C. or less, during the HVPE process or the chamber clean process. In other examples, the exhaust conduit may be heated during the HVPE process or the chamber clean process to a temperature within a range from about 30° C. to about 200° C., preferably, from about 30° C. to about 170° C., more preferably, from about 30° C. to about 150° C., more preferably, from about 50° C. to about 120° C., and more preferably, from about 50° C. to about 100° C.

The processing chamber may have an internal pressure of about 760 Torr or less during the HVPE process or the chamber clean process, preferably, within a range from about 100 Torr to about 760 Torr, more preferably, from about 200 Torr to about 760 Torr, and more preferably, from about 350 Torr to about 760 Torr, for example, about 450 Torr. In some examples, the clean gas contains chlorine gas at a concentration within a range from about 1 mol % to about 10 mol %, preferably, from about 3 mol % to about 7 mol %, and more preferably, from about 4 mol % to about 6 mol %, for example, about 5 mol %.

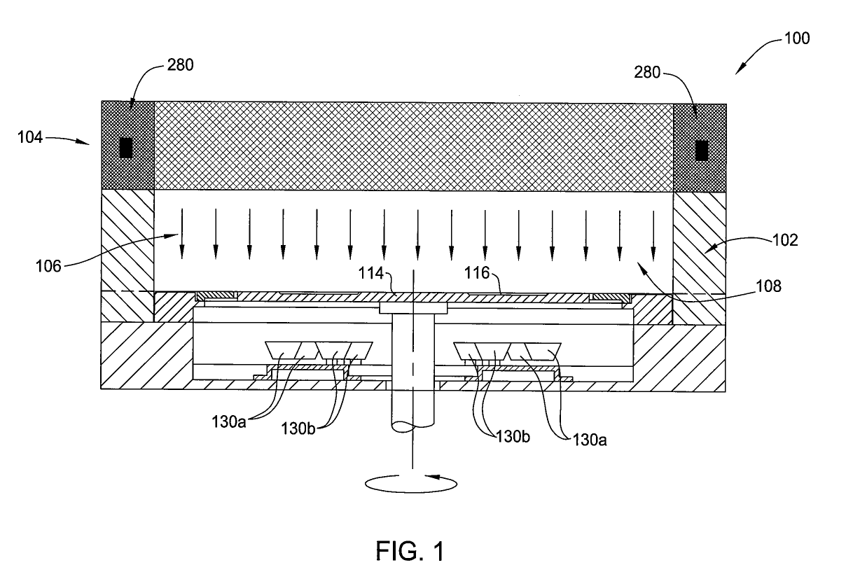

In another embodiment, vapor deposition processes and chamber clean processes as described herein may be performed within a processing chamber similar to the HVPE chamber depicted in FIG. 1. Exemplary processing chambers that may be adapted to practice embodiments of the invention are described in commonly assigned U.S. Ser. No. 11/411,672, filed Apr. 26, 2006, and published as US 2007-0254100, and U.S. Ser. No. 11/404,516, filed Apr. 14, 2006, and published as US 2007-0240631, which are incorporated by reference in their entirety.

The apparatus 100 in FIG. 1 includes a chamber body 102 that encloses a processing volume 108. A showerhead assembly 104 is disposed at one end of the processing volume 108, and a substrate carrier 114 is disposed at the other end of the processing volume 108. The substrate carrier 114 may include one or more recesses 116 within which one or more substrates may be disposed during processing. The substrate carrier 114 may carry six or more substrates. In one embodiment, the substrate carrier 114 carries eight substrates. It is to be understood that more or less substrates may be carried on the substrate carrier 114. Typical substrates may be sapphire, silicon carbide or silicon. Substrate size may range from 50 mm⁻¹⁰⁰ mm in diameter or larger. The substrate carrier size may range from 200 mm-500 mm. The substrate carrier may be formed from a variety of materials, including silicon carbide or silicon carbide-coated graphite. It is to be understood that the substrates may contain sapphire, silicon carbide, gallium nitride, silicon, quartz, gallium arsenide, aluminum nitride, glass, or derivatives thereof. It is to be understood that substrates of other sizes may be processed within the apparatus 100 and according to the processes described herein. The showerhead assembly, as described above, may allow for more uniform deposition across a greater number of substrates or larger substrates than in traditional HVPE chambers, thereby reducing production costs. The substrate carrier 114 may rotate about its central axis during processing. In one embodiment, the substrates may be individually rotated within the substrate carrier 114.

The substrate carrier 114 may be rotated. In one embodiment, the substrate carrier 114 may be rotated at about 2 RPM to about 100 RPM. In another embodiment, the substrate carrier 114 may be rotated at about 30 RPM. Rotating the substrate carrier 114 aids in providing uniform exposure of the processing gases to each substrate.

A plurality of lamps 130a, 130b may be disposed below the substrate carrier 114. For many applications, a typical lamp arrangement may comprise banks of lamps above (not shown) and below (as shown) the substrate. One embodiment may incorporate lamps from the sides. In certain embodiments, the lamps may be arranged in concentric circles. For example, the inner array of lamps 130b may include eight lamps, and the outer array of lamps 130a may include twelve lamps. In one embodiment of the invention, the lamps 130a, 130b are each individually powered. In another embodiment, arrays of lamps 130a, 130b may be positioned above or within showerhead assembly 104. It is understood that other arrangements and other numbers of lamps are possible. The arrays of lamps 130a, 130b may be selectively powered to heat the inner and outer areas of the substrate carrier 114. In one embodiment, the lamps 130a, 130b are collectively powered as inner and outer arrays in which the top and bottom arrays are either collectively powered or separately powered. In yet another embodiment, separate lamps or heating elements may be positioned over and/or under the source boat 280. It is to be understood that the invention is not restricted to the use of arrays of lamps. Any suitable heating source may be utilized to ensure that the proper temperature is adequately applied to the processing chamber, substrates therein, and a metal source. For example, it is contemplated that a rapid thermal processing lamp system may be utilized such as is described in commonly assigned U.S. Ser. No. 11/187,188, filed Jul. 22, 2005, and published as US 2006-0018639, which is incorporated by reference in its entirety.

One or more lamps 130a, 130b may be powered to heat the substrates as well as the source boat 280. The lamps may heat the substrate to a temperature within a range from about 900° C. to about 1,200° C. In another embodiment, the lamps 130a, 130b maintain the metal source in well 820 within the source boat 280 at a temperature within a range from about 350° C. to about 900° C. A thermocouple may be positioned within the well 820 to measure the metal source temperature during processing. The temperature measured by the thermocouple may be fed back to a controller that adjusts the heat provided from the heating lamps 130a, 130b so that the temperature of the metal source in well 820 may be controlled or adjusted as necessary.

During the process according to one embodiment of the invention, precursor gases 106 flow from the showerhead assembly 104 towards the substrate surface. Reaction of the precursor gases 106 at or near the substrate surface may deposit various metal nitride layers upon the substrate, including GaN, AlN, and InN. Multiple metals may also be utilized for the deposition of “combination films” such as AlGaN and/or InGaN. The processing volume 108 may be maintained at a pressure within a range from about 100 Torr to about 760 Torr. In one example, the processing volume 108 is maintained at a pressure within a range from about 450 Torr to about 760 Torr.

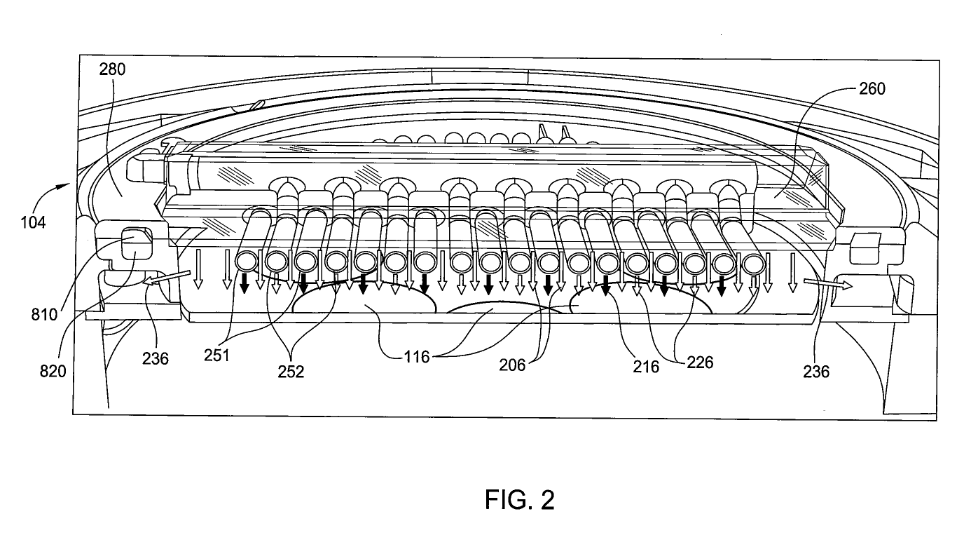

FIG. 2 is a cross-sectional perspective of the HVPE chamber of FIG. 1, according to one embodiment of the invention. A source boat 280 encircles the chamber body 102. A metal source fills the well 820 of the source boat 280. In one embodiment, the metal source includes any suitable metal source, such as gallium, aluminum, or indium, with the particular metal selected based on the particular application needs. A halide or halogen gas flows through channel 810 above the metal source in well 820 of the source boat 280 and reacts with the metal source to form a gaseous metal-containing precursor. In one embodiment, HCl reacts with liquid gallium to form gaseous GaCl. In another embodiment, Cl₂ reacts with liquid gallium to form GaCl and GaCl₃. Additional embodiments of the invention utilize other halides or halogens to attain a metal-containing gas phase precursor. Suitable hydrides include those with composition HX (e.g., with X=Cl, Br, or I) and suitable halogens include Cl₂, Br₂, and I₂. For halides, the unbalanced reaction equation is:

HX(gas)+M(liquid metal)→MX(gas)+H(gas)

where X=Cl, Br, or I and M=Ga, Al, or In. For halogens the equation is:

Z(gas)+M(liquid metal)→MZ(gas)

where Z=Cl₂, Br₂, or I₂ and M=Ga, Al, or In. Hereafter the gaseous metal containing specie will be referred to as the “metal containing precursor” (e.g., metal chloride).

The metal containing precursor gas 216 from the reaction within the source boat 280 is introduced into the processing volume 108 through a first set of gas passages, such as tubes 251. It is to be understood that metal containing precursor gas 216 may be generated from sources other than source boat 280. A nitrogen-containing gas 226 may be introduced into the processing volume 108 through a second set of gas passages, such as tubes 252. While an arrangement of tubes are shown as an example of a suitable gas distribution structure and may be utilized in some embodiments, a variety of other types of arrangements of different type passages designed to provide gas distribution as described herein may also be utilized for other embodiments. Examples of such an arrangement of passages include a gas distribution structure having (as passages) gas distribution channels formed in a plate, as described in greater detail below.

In one embodiment, the nitrogen-containing gas includes ammonia. The metal containing precursor gas 216 and the nitrogen-containing gas 226 may react near or at the surface of the substrate, and a metal nitride may be deposited onto the substrates. The metal nitride may deposit on the substrates at a rate of about 1 microns per hour to about 60 microns per hour. In one embodiment, the deposition rate is about 15 microns per hour to about 25 microns per hour.

In one embodiment, an inert gas 206 is introduced into the processing volume 108 through plate 260. By flowing inert gas 206 between the metal containing precursor gas 216 and the nitrogen-containing gas 226, the metal containing precursor gas 216 and the nitrogen-containing gas 226 may not contact each other and prematurely react to deposit on undesired surfaces. In one embodiment, the inert gas 206 includes hydrogen, nitrogen, helium, argon or combinations thereof. In another embodiment, ammonia is substituted for the inert gas 206. In one embodiment, the nitrogen-containing gas 226 is provided to the processing volume at a rate of about 1 slm to about 15 slm. In another embodiment, the nitrogen-containing gas 226 is co-flowed with a carrier gas. The carrier gas may include nitrogen gas or hydrogen gas or an inert gas. In one embodiment, the nitrogen-containing gas 226 is co-flowed with a carrier gas which may be provided at a flow rate within a range from about 0 slm to about 15 slm. Typical flow rates for halide or halogen gas is within a range from about 5 sccm to about 1,000 sccm but may include flow rates up to about 5 slm. Carrier gas for the halide/halogen gas may be within a range from about 0.1 μm to about 10 slm and contains the inert gases listed previously. Additional dilution of the halide/halogen/carrier gas mixture may occur with an inert gas within a range from about 0 slm to about 10 slm. Flow rates for inert gas 206 may be within a range from about 5 slm to about 40 slm. Process pressure varies within a range from about 100 Torr to about 1,000 Torr. The substrate may be heated to a temperature within a range from about 500° C. to about 1,200° C.

The inert gas 206, metal containing precursor gas 216, and the nitrogen-containing gas 226 may exit the processing volume 108 through exhausts 236, which may be distributed about the circumference of the processing volume 108. Such a distribution of exhausts 236 may provide for uniform flow of gases across the surface of the substrate.

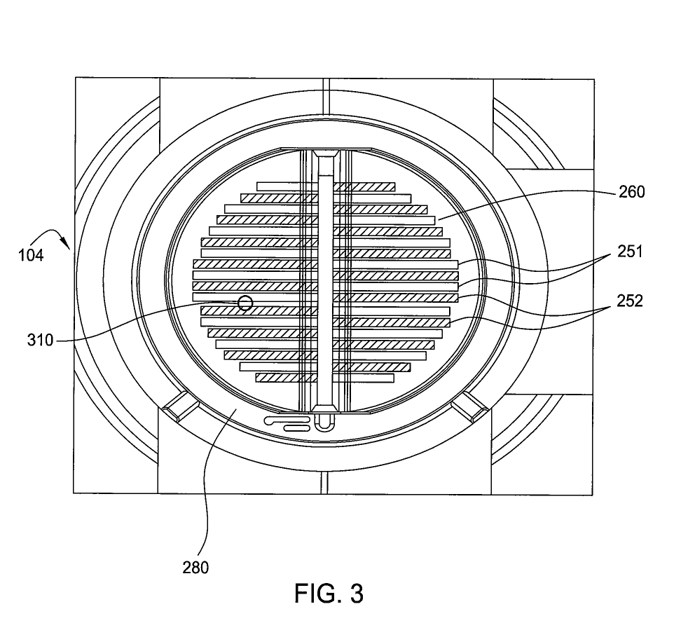

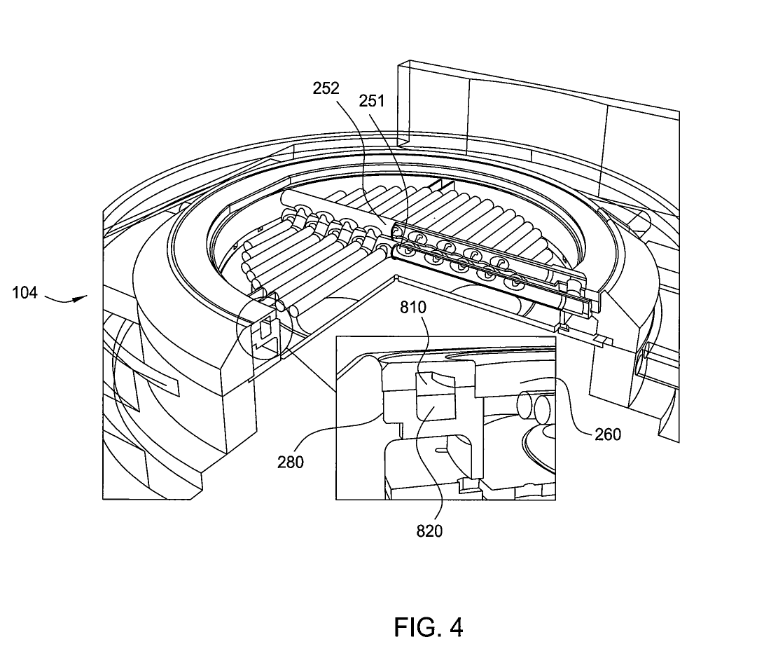

As shown in FIGS. 3 and 4, the gas tubes 251 and gas tubes 252 may be interspersed, according to one embodiment of the invention. The flow rate of the metal containing precursor gas 216 within gas tubes 251 may be controlled independently of the flow rate of the nitrogen-containing gas 226 within gas tubes 252. Independently controlled, interspersed gas tubes may contribute to greater uniformity of distribution of each of the gases across the surface of the substrate, which may provide for greater deposition uniformity.

Additionally, the extent of the reaction between metal containing precursor gas 216 and nitrogen-containing gas 226 will depend on the time the two gases are in contact. By positioning gas tubes 251 and gas tubes 252 parallel to the surface of the substrate, metal containing precursor gas 216 and nitrogen-containing gas 226 will come into contact simultaneously at points equidistant from gas tubes 251 and gas tubes 252, and will therefore react to generally the same extent at all points on the surface of the substrate. Consequently, deposition uniformity can be achieved with substrates of larger diameters. It should be appreciated that variation of distance between the surface of the substrate and gas tubes 251 and gas tubes 252 will govern the extent to which metal containing precursor gas 216 and nitrogen-containing gas 226 will react. Therefore, according to one embodiment of the invention, this dimension of the processing volume 108 may be varied during the deposition process. Also, according to another embodiment of the invention, the distance between gas tubes 251 and the surface of the substrate may be different from the distance between gas tubes 252 and the surface of the substrate. In addition, separation between the gas tubes 251 and 252 may also prevent reaction between the metal containing and nitrogen-containing precursor gases and unwanted deposition at or near the tubes 251 and 252. As will be described below, an inert gas may also be flowed between the tubes 251 and 252 to help maintain separation between the precursor gases.

In one embodiment of the invention, a metrology viewport 310 may be formed in plate 260. This may provide access for radiation measurement instruments to processing volume 108 during processing. Such measurements may be made by an interferometer to determine the rate at which a film is depositing on a substrate by comparing reflected wavelength to transmitted wavelength. Measurements may also be made by a pyrometer to measure substrate temperature. It should be appreciate that metrology viewport 310 may provide access to any radiation measurement instruments commonly used in conjunction with HVPE.

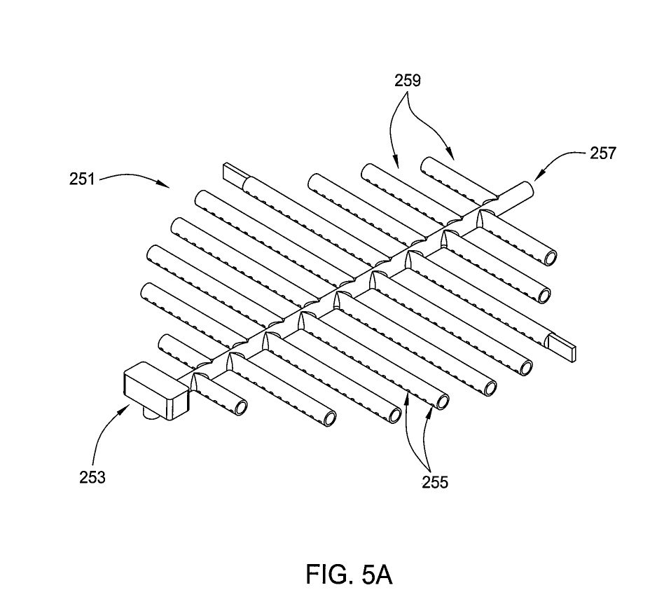

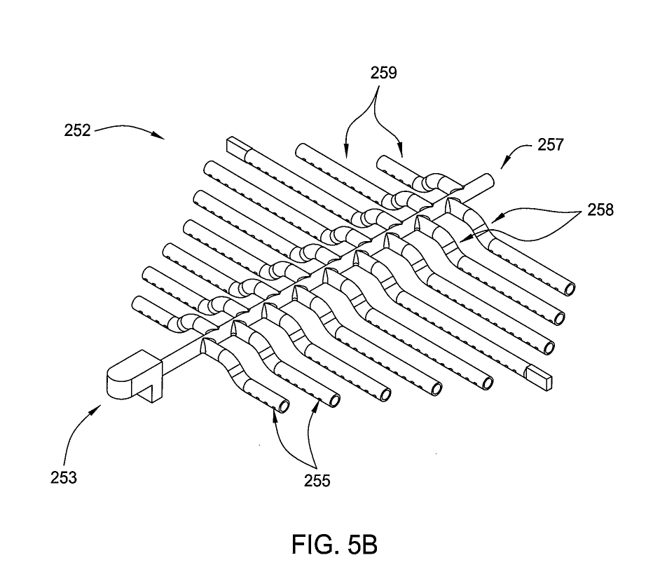

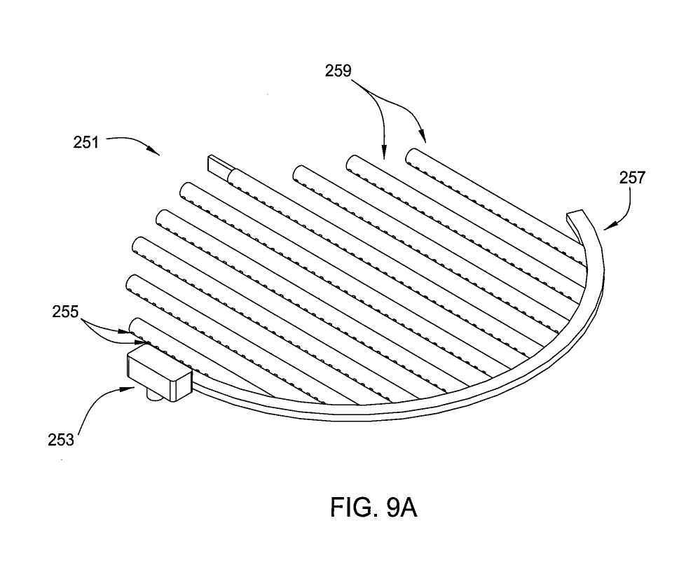

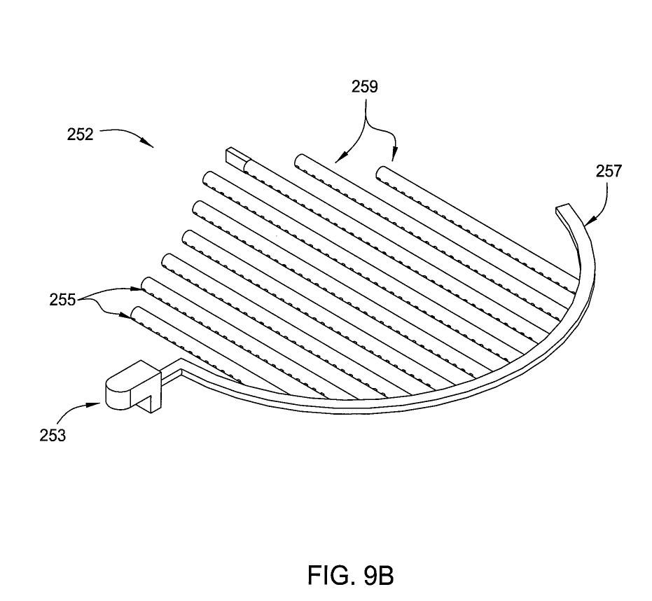

Interspersing of gas tubes 251 and gas tubes 252 may be achieved by constructing the tubes as shown in FIG. 5, according to one embodiment of the invention. Each set of tubes may essentially include a connection port 253, connected to a single trunk tube 257, which is also connected to multiple branch tubes 259. Each of the branch tubes 259 may have multiple gas ports 255 formed on the side of the tubes which generally faces the substrate carrier 114. The connection port 253 of gas tubes 251 may be constructed to be positioned between the connection port 253 of gas tubes 252 and the processing volume 108. The trunk tube 257 of gas tubes 251 would then be positioned between the trunk tube 257 of gas tubes 252 and the processing volume 108. Each branch tube 259 of gas tube 252 may contain an “S” bend 258 close to the connection with trunk tube 257 so that the length of the branch tubes 259 of gas tubes 252 would be parallel to, and aligned with, branch tubes 259 of gas tubes 251. Similarly, interspersing of gas tubes 251 and gas tubes 252 may be achieved by constructing the tubes as shown in FIG. 9, according to another embodiment of the invention which is discussed below. It is to be understood that the number of branch tubes 259, and, consequently, the spacing between adjacent branch tubes, may vary. Larger distances between adjacent branch tubes 259 may reduce premature deposition on the surface of the tubes. Premature deposition may also be reduced by adding partitions between adjacent tubes. The partitions may be positioned perpendicular to the surface of the substrate, or the partitions may be angled so as to direct the gas flows. In one embodiment of the invention, the gas ports 255 may be formed to direct metal containing precursor gas 216 at an angle to nitrogen-containing gas 226.

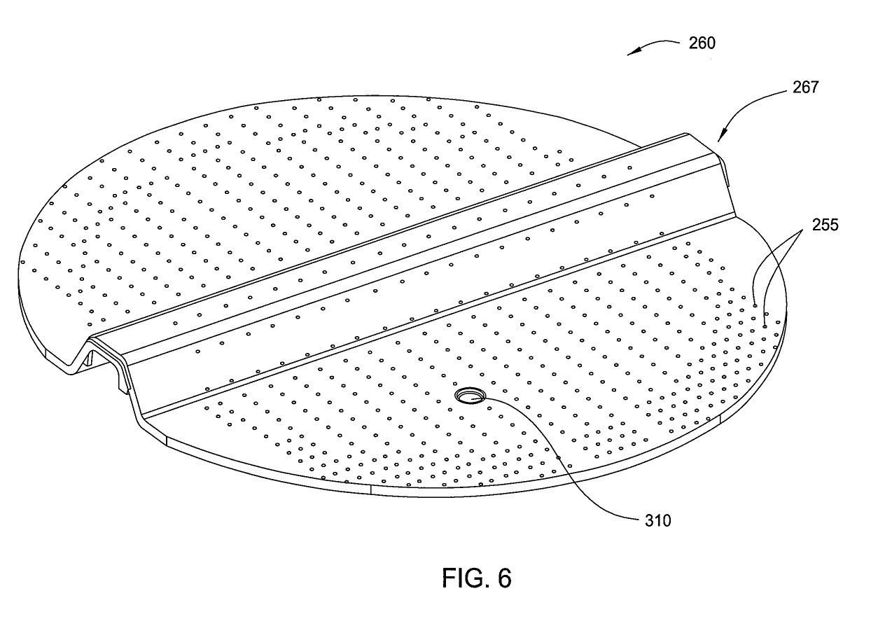

FIG. 6 shows plate 260, according to one embodiment of the invention. As previously described, inert gas 206 may be introduced into the processing volume 108 through multiple gas ports 255 distributed across the surface of plate 260. Notch 267 of plate 260 accommodates the positioning of trunk tube 257 of gas tubes 252, according to one embodiment of the invention. Inert gas 206 may flow between the branch tubes 259 of gas tubes 251 and gas tubes 252, thereby maintaining separation of the flow of metal containing precursor gas 216 from nitrogen-containing gas 226 until the gases approach the surface of the substrate, according to one embodiment of the invention.

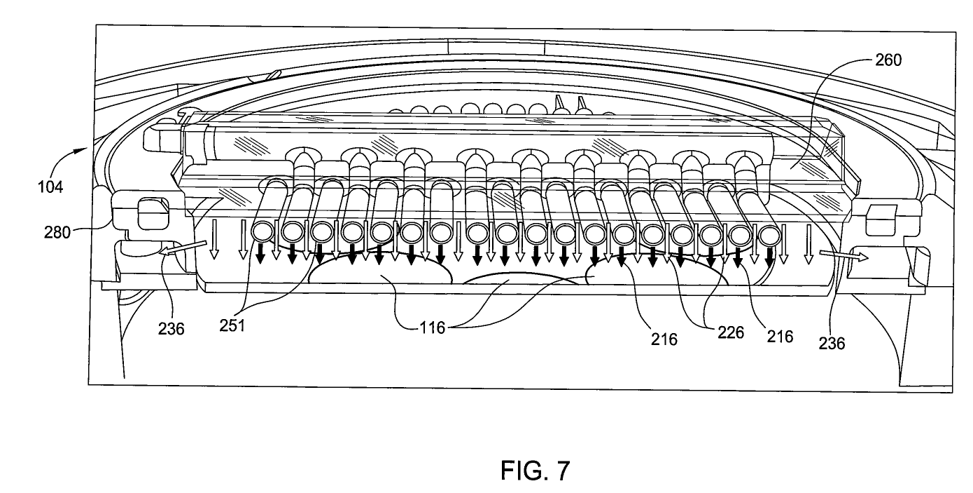

According to one embodiment of the invention, shown in FIG. 7, nitrogen-containing gas 226 may be introduced into processing volume 108 through plate 260. According to this embodiment, branch tubes 259 of gas tubes 252 are replaced by additional branch tubes 259 of gas tube 251. Metal containing precursor gas may thereby be introduced into processing volume 108 through gas tubes 252.

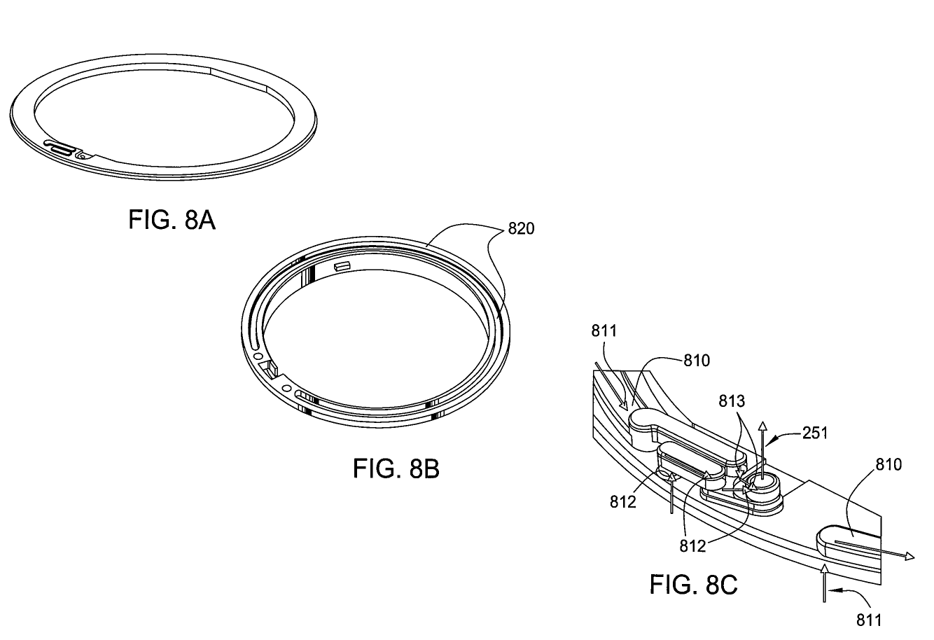

FIG. 8 shows the components of the source boat 280, according to one embodiment of the invention. The boat may be made up of a top portion (FIG. 8A) which covers a bottom portion (FIG. 8B). Joining the two portions creates an annular cavity made up of a channel 810 above a well 820. As previously discussed, chlorine containing gas 811 may flow through the channel 810 and may react with a metal source in the well 820 to produce a metal containing precursor gas 813. According to one embodiment of the invention, metal containing precursor gas 813 may be introduced through gas tubes 251 into processing volume 108 as the metal containing precursor gas 216.

In another embodiment of the invention, metal containing precursor gas 813 may be diluted with inert gas 812 in the dilution port shown in FIG. 8C. Alternatively, inert gas 812 may be added to chlorine containing gas 811 prior to entering channel 810. Additionally, both dilutions may occur; that is, inert gas 812 may be added to chlorine containing gas 811 prior to entering channel 810, and additional inert gas 812 may be added at the exit of channel 810. The diluted metal containing precursor gas is then introduced through gas tubes 251 into processing volume 108 as the metal containing precursor gas 216. The residence time of the chlorine containing gas 811 over the metal source will be directly proportional to the length of the channel 810. Longer residence times generate greater conversion efficiency of the metal containing precursor gas 216. Therefore, by encircling chamber body 102 with source boat 280, a longer channel 810 can be created, resulting in greater conversion efficiency of the metal containing precursor gas 216. A typical diameter of top portion (FIG. 8A) or bottom portion (FIG. 8B), which make up channel 810, is in the range of 10-12 inches. The length of channel 810 is the circumference of top portion (FIG. 8A) and bottom portion (FIG. 8B) and is in the range of 30-40 inches.

FIG. 9 shows another embodiment of the invention. In this embodiment, trunk tubes 257 of gas tubes 251 and 252 may be reconfigured to follow the perimeter of processing volume 108. By moving the trunk tubes 257 to the perimeter, the density of gas ports 255 may become more uniform across the surface of the substrate. It is to be understood that other configurations of trunk tubes 257 and branch tubes 259, with complimentary reconfigurations of plate 260, are possible.

Those skilled in the art will recognize that a variety of modifications may be made from the embodiments described above, while still staying within the scope of the present invention. As an example, as an alternative (or in addition) to an internal boat, some embodiments may utilize a boat that is located outside the chamber. For some such embodiments, a separate heating source and/or heated gas lines may be used to deliver precursor from the external boat to the chamber.

For some embodiments, some type of mechanism may be utilized to all a boat located within a chamber to be refilled (e.g., with liquid metal) without opening the chamber. For example, some type of apparatus utilizing an injector and plunger (e.g., similar to a large-scale syringe) may be located above the boat so that the boat can be refilled with liquid metal without opening the chamber.

For some embodiments, an internal boat may be filled from an external large crucible that is connected to the internal boat. Such a crucible may be heated (e.g., resistively or via lamps) with a separate heating and temperature control system. The crucible may be used to “feed” the boat by various techniques, such as a batch process where an operator opens and closes manual valves, or through the use of process control electronics and mass flow controllers.

For some embodiments, a flash vaporization technique may be utilized to deliver metal precursors into the chamber. For example, flash vaporize metal precursor may be delivered via a liquid injector to inject small amounts of metal into the gas stream.

For some embodiments, some form of temperature control may be utilized to maintain precursor gases in an optimal operating temperature. For example, a boat (whether internal or external) may be fitted with a temperature sensor (e.g., a thermocouple) in direct contact to determine temperature of the precursor in the boat. This temperature sensor may be connected with an automatic feedback temperature control. As an alternative to a directly contacting temperature sensor, remote pyrometry may be utilized to monitor boat temperature.

For an external boat design, a variety of different types of showerhead designs (such as those described above and below) may be utilized. Such showerheads may be constructed from suitable material that can withstand extreme temperatures (e.g., up to 1,000° C.) such as silicon carbide or quartz or silicon carbide-coated graphite. As described above, tube temperature may be monitored via thermocouples or remote pyrometry.

For some embodiments, banks of lamps located from top and bottom of chamber may be tuned to adjust tube temperature as necessary to accomplish a variety of goals. Such goals may include minimizing deposition on tubes, maintaining a constant temperature during the deposition process, and ensuring a maximum temperature bound is not exceeded (in order to minimize damage due to thermal stresses).

The components shown in FIGS. 5A-B, 6, 8A-C, and 9A-9B may be constructed from any suitable materials, such as silicon carbide, silicon carbide-coated graphite, and/or quartz and may have any suitable physical dimensions. For example, for some embodiments, the showerhead tubes shown in FIGS. 5A-5B and 9A-9B may have a wall thickness within a range from about 1 mm to about 10 mm (e.g., about 2 mm in some applications).

The tubes may also be constructed in a manner that prevents damage from chemical etching and/or corrosion. For example, the tubes may include some type of coating, such as silicon carbide or some other suitable coating that minimizes damage from chemical etching and corrosion. As an alternative, or in addition, the tubes may be surrounded by a separate part that shields the tubes from etching and corrosion. For some embodiments, a main (e.g., center) tube may be quartz while branch tubes may be silicon carbide.

In some applications, there may be a risk of deposits forming on the tubes, which may impede performance, for example, by clogging gas ports. For some embodiments, to prevent or minimize deposition, some type of barrier (e.g., baffles or plates) may be placed between the tubes. Such barriers may be designed to be removable and easily replaceable, thereby facilitating maintenance and repair.

While showerhead designs utilizing branch tubes have been described herein, for some embodiments, the tube construction may be replaced with a different type of construction designed to achieve a similar function. As an example, for some embodiments, delivery channels and holes may be drilled into a single-piece plate that provides a similar function as the tubes in terms of gas separation and delivery into the main chamber. As an alternative, rather than a single piece, a distribution plate may be constructed via multiple parts that can be fit together or assembled in some way (e.g., bonded, welded, or braised).

For other embodiments, solid graphite tubes may be formed, coated with silicon carbide, and the graphite may be subsequently removed to leave a series of channels and holes. For some embodiments showerheads may be constructed with various shaped (e.g., elliptical, round, rectangular, or square) clear or opaque quartz plates with holes formed therein. Suitably dimensioned tubing (e.g., channels having 2 mm ID×4 mm OD) may be fused to the plates for gas delivery.

For some embodiments, various components may be made of dissimilar materials. In such cases, measures may be taken in an effort to ensure components fit securely and prevent gas leakage. As an example, for some embodiments, a collar may be used to securely fit a quartz tube into a metal part in order to prevent gas leakage. Such collars may be made of any suitable material, for example, that allows for thermal expansion differences of the dissimilar parts that causes the parts to expand and contract by different amounts, which might otherwise cause damage to the parts or gas leakage.

As described above (e.g., with reference to FIG. 2), halide and halogen gases may be utilized in a deposition process. In addition, the aforementioned halides and halogens may be utilized as etchant gases for in-situ cleaning of the reactor. Such a cleaning process may involve flowing a halide or halogen gas (either with or without an inert carrier gas) into the chamber. At temperatures from about 100° C. to about 1,200° C., etchant gases may remove deposition from reactor walls and surfaces. Flow rates of enchant gases vary from about 1 slm to about 20 slm and flow rates of inert carrier gases vary from about 0 slm to about 20 slm. Corresponding pressures may vary from about 100 Torr to about 1,000 Torr and chamber temperature may vary from about 20° C. to about 1,200° C.

Further, the aforementioned halide and halogen gases may be utilized in a pretreatment process of substrates, for example, to promote high-quality film growth. One embodiment may involve flowing a halide or halogen gas into the chamber through tubes 251 or through plate 260 without flowing through the boat 280. Inert carrier and/or dilution gases may combine with the halide or halogen gas. Simultaneously NH₃ or similar nitrogen containing precursor may flow through tubes 252. Another embodiment of the pretreatment may provide flowing only a nitrogen-containing precursor with or without inert gases. Additional embodiments may have a series of two or more discrete steps, each of which may be different with respect to duration, gases, flow rates, temperature and pressure. Typical flow rates for halide or halogen are within a range from about 50 sccm to about 1,000 sccm but may include flow rates up to about 5 slm. Carrier gas for the halide/halogen gas may have a flow rate within a range from about 1 slm to about 40 slm and contains inert gases listed previously. Additional dilution of the halide/halogen/carrier gas mixture may occur with an inert gas having a flow rate within a range from about 0 slm to about 10 slm. The flow rate of NH₃ is within a range from about 1 slm to about 30 slm and is typically greater than the etchant gas flow rate. Process pressure may vary within a range from about 100 Torr to about 1,000 Torr. Typical substrate temperatures may be within a range from about 500° C. to about 1,200° C.

In addition, Cl₂ plasma may be generated for cleaning/deposition processes. Further, chambers described herein may be implemented as part of a multi-chamber system described in commonly assigned U.S. Ser. No. 11/404,516, filed Apr. 14, 2006, and published as US 2007-0240631, which is herein incorporated by reference in its entirety. As described therein, a remote plasma generator may be included as part of the chamber hardware, which can be utilized in the HVPE chamber described herein. Gas lines and process control hardware/software for both deposition and cleaning processes described in the application may also apply to the HVPE chamber described herein. For some embodiments, chlorine gas or plasma may be delivered from above a top plate, such as that shown in FIG. 6, or delivered through tubes that deliver a Ga-containing precursor. The type of plasma that could be utilized is not limited exclusively to chlorine, but may include fluorine, iodine, or bromine. The source gases used to generate plasma may be halogens, such as Cl₂, Br₂, or I₂, or may be gases that contain Group V elements (e.g., N, P, or As), such as NF₃.

While the foregoing is directed to embodiments of the present invention, other and further embodiments of the invention may be devised without departing from the basic scope thereof, and the scope thereof is determined by the claims that follow.

1. A method for forming a gallium nitride material on a substrate, comprising:
heating a solid metallic gallium source to form a liquid metallic gallium source;
exposing the liquid metallic gallium source to chlorine gas (Cl₂) to form a gallium chloride gas; and
exposing a substrate within a processing chamber to the gallium chloride gas and a nitrogen precursor gas comprising ammonia while forming a gallium nitride layer on the substrate during a hydride vapor phase epitaxy process.

2. The method of claim 1, wherein the substrate is heated to a temperature within a range from about 800° C. to about 1,100° C. during the hydride vapor phase epitaxy process.

3. The method of claim 1, wherein the substrate is exposed to a pretreatment gas comprising chlorine gas during a pretreatment process prior to forming the gallium nitride layer.

4. The method of claim 3, wherein the pretreatment gas further comprises ammonia or gallium chloride, and the pretreatment gas further comprises argon, nitrogen, hydrogen, or combinations thereof.

5. The method of claim 3, wherein the substrate is heated to a temperature within a range from about 500° C. to about 1,250° C. during the pretreatment process, and the chlorine gas has a flow rate within a range from about 50 sccm to about 1,000 sccm during the pretreatment process.

6. The method of claim 1, wherein the processing chamber is exposed to the chlorine gas during a chamber clean process subsequent to forming the gallium nitride layer.

7. The method of claim 6, wherein the processing chamber is heated to a temperature within a range from about 500° C. to about 1,250° C. during the chamber clean process.

8. The method of claim 6, wherein the processing chamber is exposed to a plasma during the chamber clean process.

9. A method for forming an aluminum nitride material on a substrate, comprising:
heating a metallic aluminum source to form a heated metallic aluminum source;
exposing the heated metallic aluminum source to chlorine gas (Cl₂) to form an aluminum chloride gas; and
exposing a substrate within a processing chamber to the aluminum chloride gas and a nitrogen precursor gas comprising ammonia while forming an aluminum nitride layer on the substrate during a hydride vapor phase epitaxy process.

10. The method of claim 9, wherein the substrate is heated to a temperature within a range from about 800° C. to about 1,100° C. during the hydride vapor phase epitaxy process.

11. The method of claim 9, wherein the substrate is exposed to a pretreatment gas comprising chlorine gas during a pretreatment process prior to forming the aluminum nitride layer.

12. The method of claim 11, wherein the pretreatment gas further comprises ammonia or aluminum chloride, and the pretreatment gas further comprises argon, nitrogen, hydrogen, or combinations thereof.

13. The method of claim 11, wherein the substrate is heated to a temperature within a range from about 500° C. to about 1,250° C. during the pretreatment process, and the chlorine gas has a flow rate within a range from about 50 sccm to about 4,000 sccm during the pretreatment process.

14. The method of claim 9, wherein the processing chamber is exposed to the chlorine gas during a chamber clean process subsequent to forming the aluminum nitride layer.

15. The method of claim 14, wherein the processing chamber is heated to a temperature within a range from about 500° C. to about 1,200° C., and the chlorine gas has a flow rate within a range from about 50 sccm to about 1,000 sccm during the pretreatment process.

16. The method of claim 14, wherein the processing chamber is exposed to a plasma during the chamber clean process.

17. A method for forming a gallium nitride material on a substrate, comprising:
exposing a substrate within a processing chamber to chlorine gas (Cl₂) while forming a pretreated surface during a pretreatment process;
heating a metallic source to form a heated metallic source, wherein the heated metallic source comprises an element selected from the group consisting of gallium, aluminum, indium, alloys thereof, and combinations thereof;
exposing the heated metallic source to a chlorine-containing gas to form a metallic chloride gas; and
exposing the substrate to the metallic chloride gas and a nitrogen precursor gas while forming a metal nitride layer on the pretreated surface during a hydride vapor phase epitaxy process.

18. The method of claim 17, wherein the chlorine-containing gas comprises hydrogen chloride or chlorine gas.

19. A method for forming a gallium nitride material on a substrate, comprising:
providing a substrate within a processing chamber coupled to an exhaust system, wherein the exhaust system comprises an exhaust conduit;
exposing the substrate to a pretreatment gas comprising chlorine gas while forming a pretreated surface during a pretreatment process, while heating the exhaust conduit to a temperature of about 100° C. or less during the pretreatment process;
heating a solid metallic gallium source to form a liquid metallic gallium source;
exposing the chlorine gas to the liquid metallic gallium source to form a gallium chloride gas; and
exposing the substrate to the gallium chloride gas and a nitrogen precursor gas while forming a gallium nitride layer on the substrate during a hydride vapor phase epitaxy process.

20. A method for forming a gallium nitride material on a substrate, comprising:
heating a metallic source to form a heated metallic source, wherein the heated metallic source comprises an element selected from the group consisting of gallium, aluminum, indium, alloys thereof, and combinations thereof;
exposing the heated metallic source to chlorine gas (Cl₂) to form a metallic chloride gas;
exposing a substrate within a processing chamber to the metallic chloride gas and a nitrogen precursor gas while forming a metal nitride layer on the substrate during a hydride vapor phase epitaxy process; and
exposing the processing chamber to the chlorine gas during a chamber clean process subsequent to forming the metal nitride layer.

21. The method of claim 20, wherein the substrate is removed from the processing chamber prior to the chamber clean process, and the processing chamber is heated to a temperature within a range from about 500° C. to about 1,200° C. during the chamber clean process.

22. The method of claim 20, wherein the substrate is removed from the processing chamber prior to the chamber clean process and the processing chamber is exposed to a plasma during the chamber clean process.

23. A method for forming a Group III nitride material on a substrate, comprising:
heating a trialkyl Group III compound to a predetermined temperature;
exposing the trialkyl Group III compound to chlorine gas (Cl₂) to form a metal chloride gas; and
exposing a substrate within a processing chamber to the metal chloride gas and a nitrogen precursor gas while forming a metal nitride layer on the substrate during a vapor deposition process.

24. The method of claim 23, wherein the trialkyl Group III compound comprises a trialkylgallium compound and the metal chloride gas comprises gallium chloride.

25. The method of claim 23, wherein the trialkyl Group III compound comprises a trialkylaluminum compound and the metal chloride gas comprises aluminum chloride.
